(19) United States
(12) Patent Application Publication
(10) Pub. No.: US 2015/0097268 A1
(43) Pub. Date: Apr. 9, 2015

(54) INDUCTOR STRUCTURE AND MANUFACTURING METHOD THEREOF

(71) Applicant: XINTEC INC., Zhongli City (TW)

(72) Inventors: Wei-Ming LAI, Taoyuan City (TW); Yu-Wen HU, Zhongli City (TW)

(21) Appl. No.: 14/483,656

(22) Filed: Sep. 11, 2014

Related U.S. Application Data
(60) Provisional application No. 61/887,889, filed on Oct. 7, 2013.

(51) Int. Cl. H01L 49/02

(52) U.S. Cl. CPC H01L 28/10
USPC 257/531; 438/381

(57) ABSTRACT

An inductor structure includes a substrate, a protection layer, a patterned first conductive layer, copper bumps, a passivation layer, a diffusion barrier layer, and an oxidation barrier layer. The protection layer is located on the substrate. The bond pads of the substrate are respectively exposed through protection layer openings. The first conductive layer is located on the surfaces of the bond pads and the protection layer adjacent to the protection layer openings. The copper bumps are located on the first conductive layer. The passivation layer is located on the protection layer and the copper bumps. At least one of the copper bumps is exposed through a passivation layer opening. The diffusion barrier layer is located on the copper bump that is exposed through the passivation layer opening. The oxidation barrier layer is located on the diffusion barrier layer.

### RELATED APPLICATIONS

This application claims priority to U.S. provisional Application Ser. No. 61/887,889, filed Oct. 7, 2013, which is herein incorporated by reference.

### BACKGROUND

1. Field of Invention

The present invention relates to an inductor structure and a manufacturing method of the inductor structure.

2. Description of Related Art

The conventional method of structuring an inductor may include a silicon substrate and copper bumps. The silicon substrate has bond pads. The copper bumps are respectively formed on the bond pads by an electrolytic deposition treatment, and the copper bumps are capable of transmitting signals with high frequencies. In the next process, a ball grid array (BGA) or conductive protruding portions may be electrically connected to the bond pads of the silicon substrate by the copper bumps. Tin material and lead material cannot be directly adhered to the copper bumps. Therefore, after the copper bumps are completely formed by the electrolytic deposition treatment, nickel layers and gold layers need to be formed on the copper bumps in sequence by another electrolytic deposition treatment. The nickel layers have high impedance property so as to prevent the gold layers and the copper bumps from fusion. Moreover, the gold layers may prevent the copper bumps from oxidation.

The BGA or the conductive protruding portions may be adhered to the copper bumps by the nickel layers and the gold layers. But in fact, only few copper bumps in the inductor structure need to be electrically connected to the conductive protruding portions or the BGA during the next process (e.g., a bumping process or a BGA process), and most of the copper bumps do not need to be electrically connected to the BGA or the conductive protruding portions. However, in general, when the inductor structure is manufactured, the nickel layer and the gold layer are electroplated on each of the copper bumps due to a limited process capability.

As a result, the materials (e.g., gold) are wasted, and the nickel layers and the gold layers electroplated on all of the copper bumps may increase the entire impedance of lines of the inductor structure and therefore reduce the efficiency of the inductor structure, such that the inductor quality factor of the inductor structure is difficultly improved.

### SUMMARY

An aspect of the present invention is to provide an inductor structure.

According to an embodiment of the present invention, an inductor structure includes a substrate, a protection layer, a patterned first conductive layer, a plurality of copper bumps, a passivation layer, a diffusion barrier layer, and an oxidation barrier layer. The substrate has a plurality of bond pads. The protection layer is located on the substrate and the bond pads and has a plurality of protection layer openings. The bond pads are respectively exposed through the protection layer openings. The patterned first conductive layer is located on surfaces of the bond pads and the protection layer adjacent to the protection layer openings. The copper bumps are located on the first conductive layer. The passivation layer is located on the protection layer and the copper bumps and has at least one passivation layer opening. At least one of the copper bumps is exposed through the passivation layer opening. The diffusion barrier layer is located on the copper bump exposed through the passivation layer opening. The oxidation barrier layer is located on the diffusion barrier layer.

In one embodiment of the present invention, the inductor structure further includes a strengthening layer. The strengthening layer is between the diffusion barrier layer and the oxidation barrier layer.

In one embodiment of the present invention, the strengthening layer is made of a material including palladium.

In one embodiment of the present invention, the passivation layer is made of a material including oxide or nitride.

In one embodiment of the present invention, the protection layer is made of a material including oxide or nitride.

In one embodiment of the present invention, the inductor structure further includes a second conductive layer. The second conductive layer is between the diffusion barrier layer and the copper bump exposed through the passivation layer opening.

In one embodiment of the present invention, the diffusion barrier layer is made of a material including nickel.

In one embodiment of the present invention, the oxidation barrier layer is made of a material including gold.

Another aspect of the present invention is to provide a manufacturing method of an inductor structure.

According to an embodiment of the present invention, a manufacturing method of an inductor structure includes the following steps. (a) A substrate having a plurality of bond pads is provided. (b) A protection layer having a plurality of protection layer openings is formed on the substrate and the bond pads, such that the bond pads are respectively exposed through the protection layer openings. (c) A first conductive layer is formed on the bond pads and the protection layer. (d) A patterned first photo-resistant layer is formed on the first conductive layer, such that the first conductive layer adjacent to the protection layer openings is exposed through a plurality of first photo-resistant layer openings. (e) A plurality of copper bumps are respectively formed on the first conductive layer in the first photo-resistant layer openings. (f) The first photo-resistant layer and the conductive layer not covered by the copper bumps are removed. (g) A patterned passivation layer is formed on the protection layer and the copper bumps, and at least one of the copper bumps exposed through a passivation layer opening. (h) A diffusion barrier layer and an oxidation barrier layer are sequentially formed on the copper bump that is exposed through the passivation layer opening.

In one embodiment of the present invention, step (h) includes: (i) a second conductive layer is formed on the passivation layer and the copper bump exposed through the passivation layer opening. (j) A patterned second photo-resistant layer is formed on the second conductive layer, and the second conductive layer in the passivation layer opening is exposed through a second photo-resistant layer opening. (k) The diffusion barrier layer and the oxidation barrier layer are sequentially formed on the second conductive layer which is exposed through the second photo-resist layer opening. (l) The second photo-resistant layer and the second conductive layer not covered by the diffusion barrier layer and the oxidation barrier layer are then removed.

In one embodiment of the present invention, step (k) includes: the diffusion barrier layer and the oxidation barrier layer are electroplated on the second conductive layer that is exposed through the second photo-resistant layer opening.

In one embodiment of the present invention, step (h) includes: the diffusion barrier layer and the oxidation barrier layer are chemically plated on the copper bump that is exposed through the passivation layer opening.

In one embodiment of the present invention, step (h) further includes: a strengthening layer that is formed between the diffusion barrier layer and the oxidation barrier layer.

In one embodiment of the present invention, step (b) includes: the protection layer that is patterned, such that the protection layer has the protection layer openings.

In one embodiment of the present invention, step (e) includes: the copper bumps are electroplated on the first conductive layer in the first photo-resistant layer openings.

In one embodiment of the present invention, step (f) includes: the first conductive layer that is not covered by the copper bumps is etched.

In the aforementioned embodiments of the present invention, the inductor structure and the manufacturing method thereof may form the diffusion barrier layer and the oxidation barrier layer on selected copper bumps, such that the diffusion barrier layer and the oxidation barrier layer are formed on the copper bumps that need to be electrically connected to the conductive protruding portions or BGA during the next process (e.g., a bumping process or a BGA process), and the diffusion barrier layer and the oxidation barrier layer are not formed on other copper bumps. As a result, the material costs of the diffusion barrier layer and the oxidation barrier layer may be reduced by the inductor structure and the manufacturing method thereof, and the entire impedance of lines of the inductor structure can be reduced to increase the efficiency of the inductor structure, such that the inductor quality factor of the inductor structure may be improved.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a top view of an inductor structure according to one embodiment of the present invention;

FIG. 2 is a cross-sectional view of the inductor structure taken along line 2-2 shown in FIG. 1;

FIG. 3 is a cross-sectional view of an inductor structure according to another embodiment of the present invention, in which the cross-sectional position is the same as in FIG. 2;

FIG. 4 is a flow chart of a manufacturing method of an inductor structure according to one embodiment of the present invention;

FIG. 5 is a cross-sectional view of bond pads shown in FIG. 4 after being exposed through protection layer openings;

FIG. 6 is a cross-sectional view of a first conductive layer after being formed on the bond pads and a protection layer shown in FIG. 5;

FIG. 7 is a cross-sectional view of a patterned first photo-resistant layer after being formed on the first conductive layer shown in FIG. 6;

FIG. 8 is a cross-sectional view of copper bumps after being formed on the first conductive layer in first photo-resistant layer openings shown in FIG. 7;

FIG. 9 is a cross-sectional view of a patterned passivation layer after being formed on the protection layer and the copper bumps shown in FIG. 8;

FIG. 10 is a cross-sectional view of a second conductive layer after being formed on the passivation layer and the copper bump that is exposed through a passivation layer opening shown in FIG. 9;

FIG. 11 is a cross-sectional view of a patterned second photo-resistant layer after being formed on the second conductive layer shown in FIG. 10; and

FIG. 12 is a cross-sectional view of a diffusion barrier layer and an oxidation barrier layer after being sequentially formed on the second conductive layer that is exposed through a second photo-resistant layer opening shown in FIG. 11.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

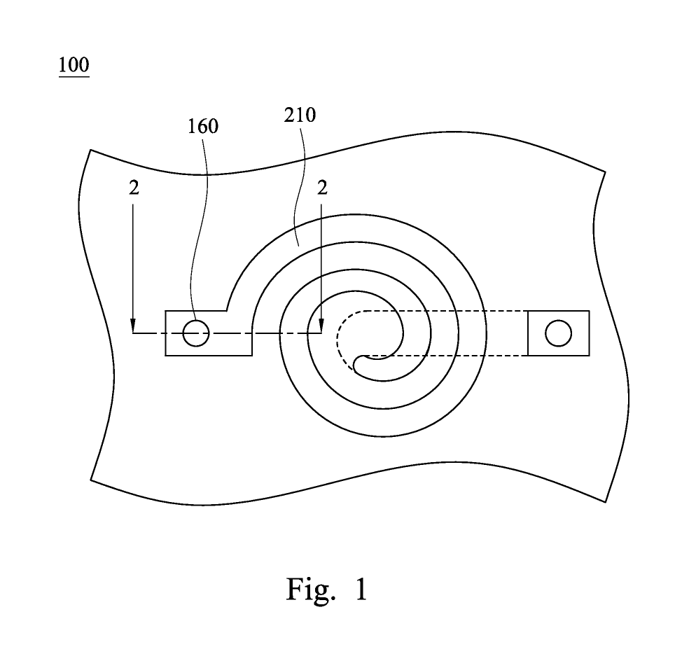

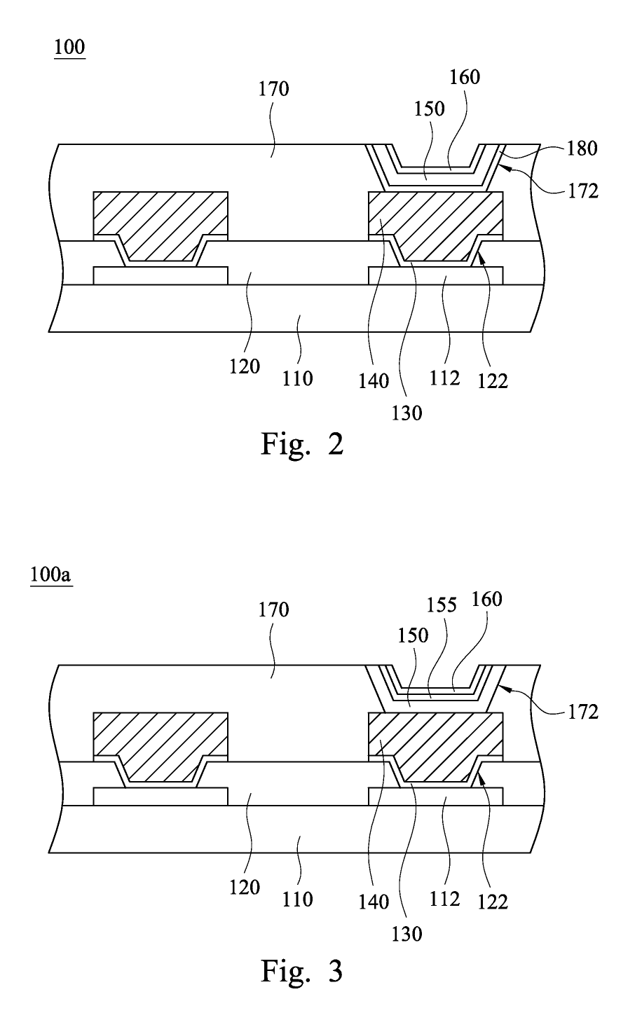

FIG. 1 is a top view of an inductor structure 100 according to one embodiment of the present invention; FIG. 2 is a cross-sectional view of the inductor structure 100 taken along line 2-2 shown in FIG. 1. In order to simplify the figures, a line layer 210 shown in FIG. 1 will not be shown in all of the cross-sectional figures. As show in FIG. 1 and FIG. 2, the inductor structure 100 includes a substrate 110, a protection layer 120, a patterned first conductive layer 130, a plurality of copper bumps 140, a passivation layer 170, a diffusion barrier layer 150, and an oxidation barrier layer 160. The substrate 110 has a plurality of bond pads 112. The protection layer 120 is located on the substrate 110 and the bond pads 112. The protection layer 120 has a plurality of protection layer openings 122, and the bond pads 112 are respectively exposed through the protection layer openings 122. The first conductive layer 130 is located on surfaces of the bond pads 112 and the protection layer 120 adjacent to the protection layer openings 122. The copper bumps 140 are located on the first conductive layer 130. The passivation layer 170 is located on the protection layer 120 and the copper bumps 140. The passivation layer 170 has at least one passivation layer opening 172, and at least one of the copper bumps 140 is exposed through the passivation layer opening 172. The diffusion barrier layer 150 is located on the copper bump 140 that is exposed through the passivation layer opening 172. The oxidation barrier layer 160 is located on the diffusion barrier layer 150.

Moreover, in this embodiment, the inductor structure 100 further includes a second conductive layer 180. The second conductive layer 180 is between the diffusion barrier layer 150 and the copper bump 140 that is exposed through the passivation layer opening 172. The diffusion barrier layer 150 and the oxidation barrier layer 160 may be formed on the second conductive layer 180 on the copper bump 140 by an electrolytic deposition treatment.

In this embodiment, the substrate 110 may be made of a material including silicon, and the protection layer 120 may be made of a material including polymer, oxide (e.g., SiO₂), or nitride. The passivation layer 170 may be made of a material including polymer, oxide or nitride, such that moisture and dust cannot enter the inductor structure 100 to prevent the copper bump 140 and the diffusion barrier layer 150 from oxidation. The bond pads 112 may be made of a material including aluminum. The first and second conductive layers 130, 180 may be made of a material including titanium and copper. The diffusion barrier layer 150 may be made of a material including nickel, thereby having high impedance property to prevent the oxidation barrier layer 160 and the copper bump 140 from fusion in a high temperature. The oxidation barrier layer 160 may be made of a material including gold to prevent the copper bump 140 from oxidation. However, the present invention is not limited by the aforesaid materials.

When the inductor structure 100 is in the next process, such as a bumping process or a ball grid array (BGA) process, a conductive protruding portion or a solder ball may be adhered to the oxidation barrier layer 160, such that the conductive protruding portion or the solder ball is electrically connected to first conductive layer 130 and the bond pad 112 by the second conductive layer 180 and the copper bump 140 with the diffusion barrier layer 150 and the oxidation barrier layer 160 (e.g., the right side copper bump shown in FIG. 2). The copper bump 140 without the diffusion barrier layer 150 and the oxidation barrier layer 160 (e.g., the left side copper bump shown in FIG. 2) is covered by the passivation layer 170, and the conductive protruding portion or the solder ball is not adhered thereto in the next process. As a result, the material costs of the diffusion barrier layer 150 and the oxidation barrier layer 160 may be reduced by the inductor structure 100, and the entire impedance of lines of the inductor structure 100 can be reduced to increase the efficiency of the inductor structure 100, such that the inductor quality factor of the inductor structure 100 may be improved.

FIG. 3 is a cross-sectional view of an inductor structure 100a according to another embodiment of the present invention, in which the cross-sectional position is the same as in FIG. 2. The inductor structure 100a includes the substrate 110, the protection layer 120, the patterned first conductive layer 130, the copper bumps 140, the passivation layer 170, the diffusion barrier layer 150, and the oxidation barrier layer 160. The difference between this embodiment and the embodiment shown in FIG. 2 is that the inductor structure 100a does not include the second conductive layer 180 (see FIG. 2), but includes a strengthening layer 155. The strengthening layer 155 is between the diffusion barrier layer 150 and the oxidation barrier layer 160, and the strengthening layer 155 may be made of a material including palladium. Moreover, the diffusion barrier layer 150, the strengthening layer 155, and the oxidation barrier layer 160 may be directly formed on the copper bump 140 by a chemical plating treatment. Although the thickness of the oxidation barrier layer 160 formed by the chemical plating treatment is thin, the strengthening layer 155 can provide supporting strength for the oxidation barrier layer 160 to prevent the oxidation barrier layer 160 from being penetrated in the next wire bond process.

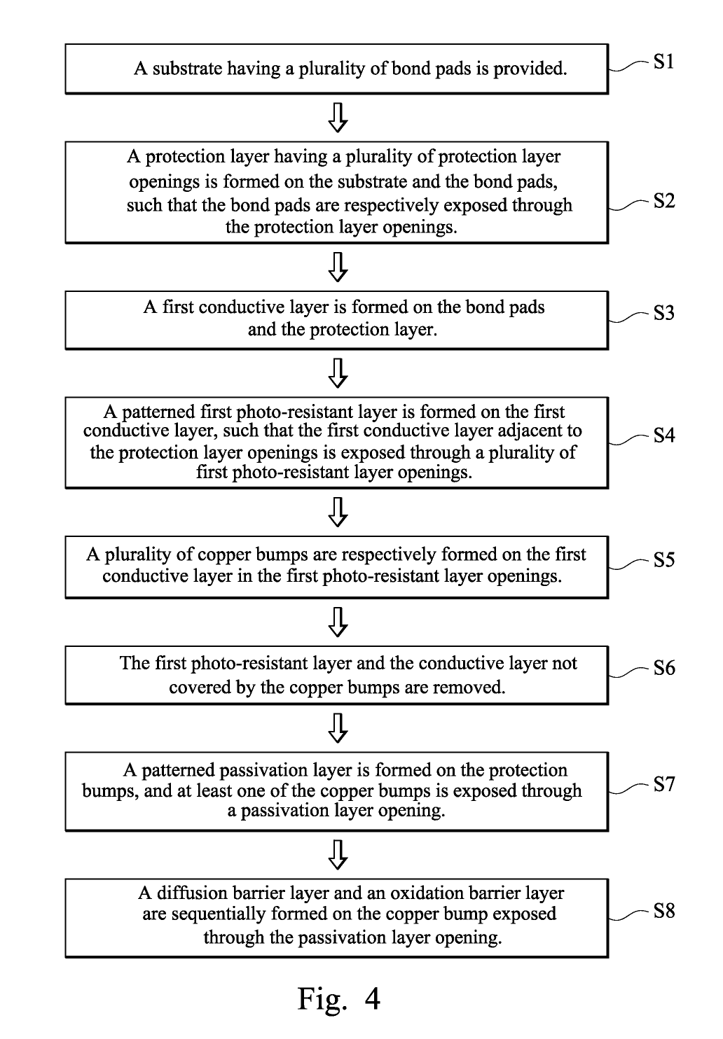

FIG. 4 is a flow chart of a manufacturing method of an inductor structure according to one embodiment of the present invention. In step S1, a substrate having a plurality of bond pads is provided. Thereafter in step S2, a protection layer having a plurality of protection layer openings is formed on the substrate and the bond pads, such that the bond pads are respectively exposed through the protection layer openings. Next in step S3, a first conductive layer is formed on the bond pads and the protection layer. Sequentially in step S4, a patterned first photo-resistant layer is formed on the first conductive layer, such that the first conductive layer adjacent to the protection layer openings is exposed through a plurality of first photo-resistant layer openings. Thereafter in step S5, a plurality of copper bumps are respectively formed on the first conductive layer in the first photo-resistant layer openings. Next in step S6, the first photo-resistant layer and the conductive layer not covered by the copper bumps are removed. Sequentially in step S7, a patterned passivation layer is formed on the protection layer and the copper bumps, and at least one of the copper bumps is exposed through a passivation layer opening. Finally in step S8, a diffusion barrier layer and an oxidation barrier layer are sequentially formed on the copper bump that is exposed through the passivation layer opening.

In the following description, the aforesaid manufacturing method of the inductor structure will be described.

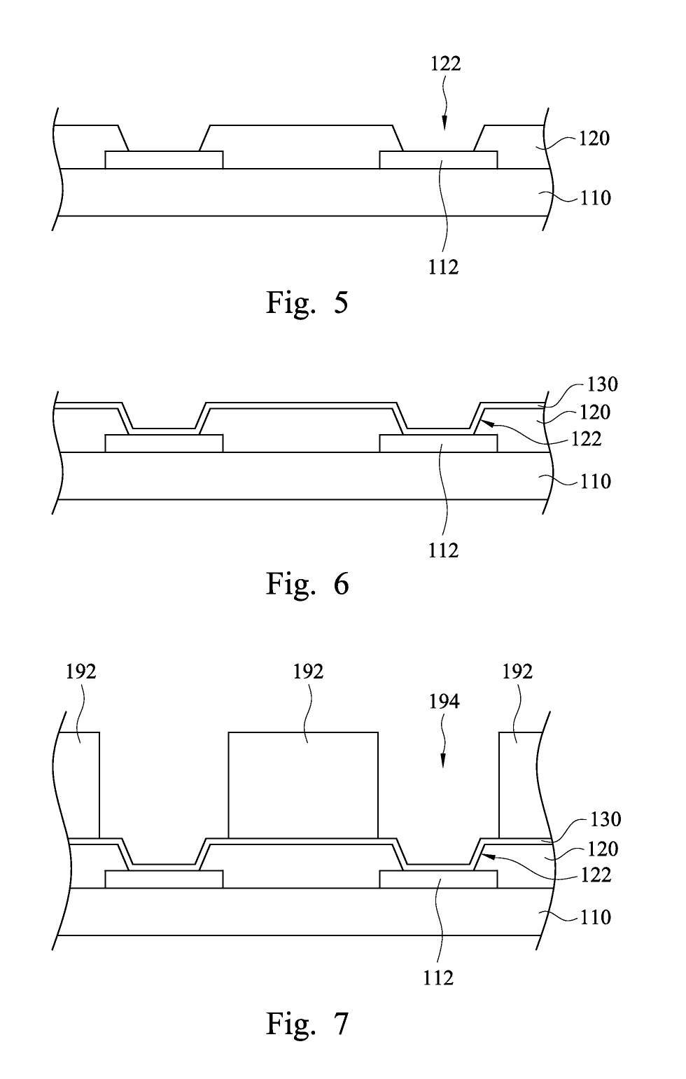

FIG. 5 is a cross-sectional view of the bond pads 112 shown in FIG. 4 after being exposed through the protection layer openings 122. As shown in FIG. 4 and FIG. 5, the substrate 110 having the bond pads 112 is provided. Thereafter, the protection layer 120 having the protection layer openings 122 is formed on the substrate 110 and the bond pads 112, such that the bond pads 112 are respectively exposed through the protection layer openings 122. A patterning process may be performed on the protection layer 120, such that the protection layer 120 has the protection layer openings 122. The patterning process may include an exposure process, a development process, and an etching process.

FIG. 6 is a cross-sectional view of the first conductive layer 130 after being formed on the bond pads 112 and the protection layer 120 shown in FIG. 5. As shown in FIG. 5 and FIG. 6, after the bond pads 112 are respectively exposed through the protection layer openings 122, the first conductive layer 130 may be formed on the bond pads 112 and the protection layer 120 by a sputtering process.

FIG. 7 is a cross-sectional view of a patterned first photo-resistant layer 192 after being formed on the first conductive layer 130 shown in FIG. 6. As shown in FIG. 6 and FIG. 7, after the first conductive layer 130 is formed on the bond pads 112 and the protection layer 120, the patterned first photo-resistant layer 192 may be formed on the first conductive layer 130, such that the first conductive layer 130 adjacent to the protection layer openings 122 is exposed through the first photo-resistant layer openings 194 of the first photo-resistant layer 192.

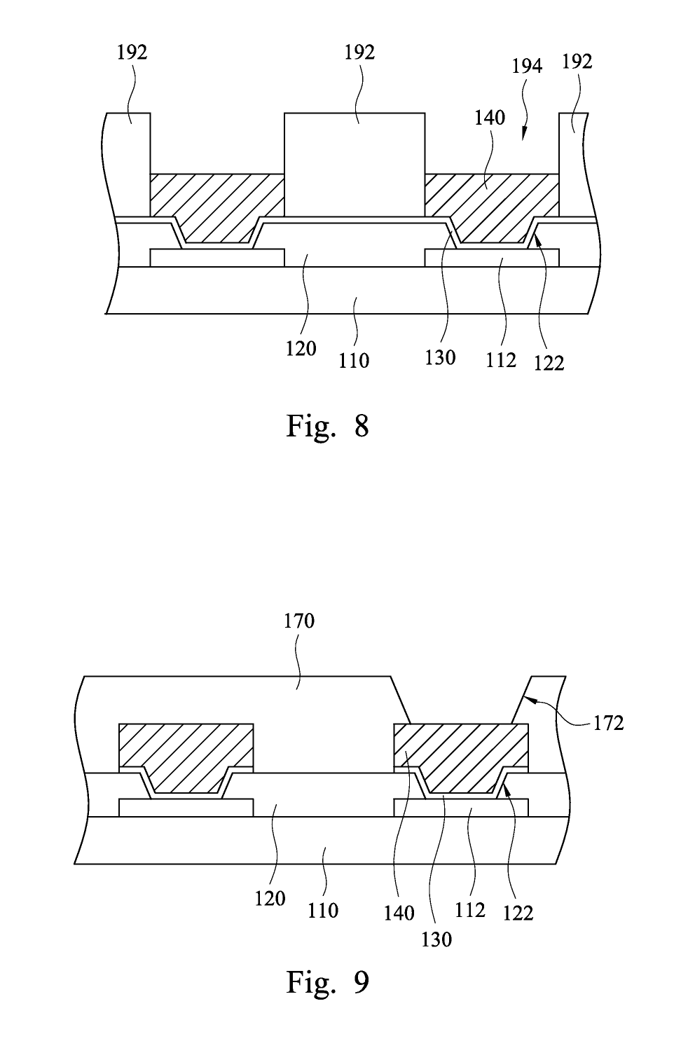

FIG. 8 is a cross-sectional view of the copper bumps 140 after being formed on the first conductive layer 130 in first photo-resistant layer openings 194 shown in FIG. 7. As shown in FIG. 7 and FIG. 8, after the patterned first photo-resistant layer 192 is formed on the first conductive layer 130, the copper bumps 140 may be respectively formed on the first conductive layer 130 in the first photo-resistant layer openings 194. The copper bumps 140 may be electroplated on the first conductive layer 130 in the first photo-resistant layer openings 194.

FIG. 9 is a cross-sectional view of the patterned passivation layer 170 after being formed on the protection layer 120 and the copper bumps 140 shown in FIG. 8. As shown in FIG. 8 and FIG. 9, after the copper bumps 140 are respectively formed on the first conductive layer 130 in the first photo-resistant layer openings 194, the first photo-resistant layer 192 and the conductive layer 130 not covered by the copper bumps 140 may be removed. For example, the conductive layer 130 not covered by the copper bumps 140 may be removed by an etching process. Thereafter, the patterned passivation layer 170 may be formed on the protection layer 120 and the copper bumps 140, and the passivation layer 170 has a passivation layer opening 172 aligned with at least one of the copper bumps 140, such that at least one of the copper bumps 140 is exposed through the passivation layer opening 172.

As shown in FIG. 3 and FIG. 9, after the copper bump 140 is exposed through the passivation layer opening 172, the diffusion barrier layer 150, the strengthening layer 155, and the oxidation barrier layer 160 may be chemically plated on the copper bump 140 that is exposed through the passivation layer opening 172. The strengthening layer 155 is formed between the diffusion barrier layer 150 and the oxidation barrier layer 160 to provide the supporting strength for the oxidation barrier layer 160. As a result, the inductor structure 100a shown in FIG. 3 may be obtained.

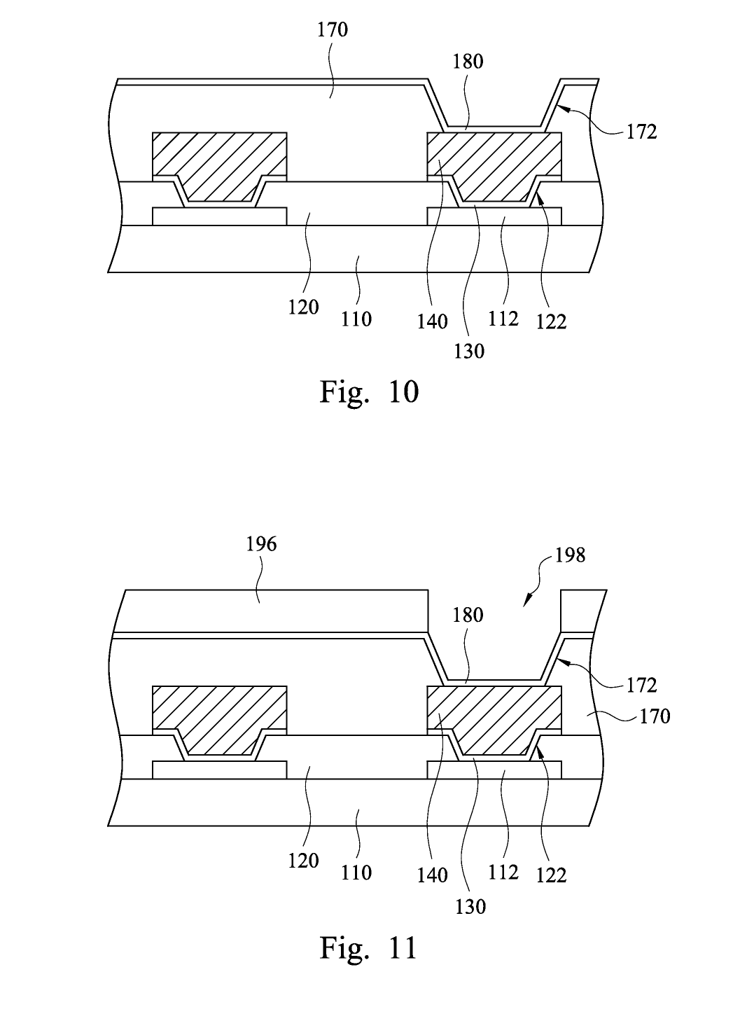

FIG. 10 is a cross-sectional view of the second conductive layer 180 after being formed on the passivation layer 170 and the copper bump 140 that is exposed through the passivation layer opening 172 shown in FIG. 9. As shown in FIG. 9 and FIG. 10, after at least one of the copper bumps 140 is exposed through the passivation layer opening 172, a sputtering treatment may be performed to form the second conductive layer 180 on the passivation layer 170 and the copper bump 140 that is exposed through the passivation layer opening 172.

FIG. 11 is a cross-sectional view of a patterned second photo-resistant layer 196 after being formed on the second conductive layer 180 shown in FIG. 10. As shown in FIG. 10 and FIG. 11, after the second conductive layer 180 is formed on the passivation layer 170 and the copper bump 140, the patterned second photo-resistant layer 196 may be formed on the second conductive layer 180, and the second photo-resistant layer 196 has a second photo-resistant layer opening 198 aligned with the passivation layer opening 172, such that the second conductive layer 180 in the passivation layer opening 172 is exposed through the second photo-resistant layer opening 198.

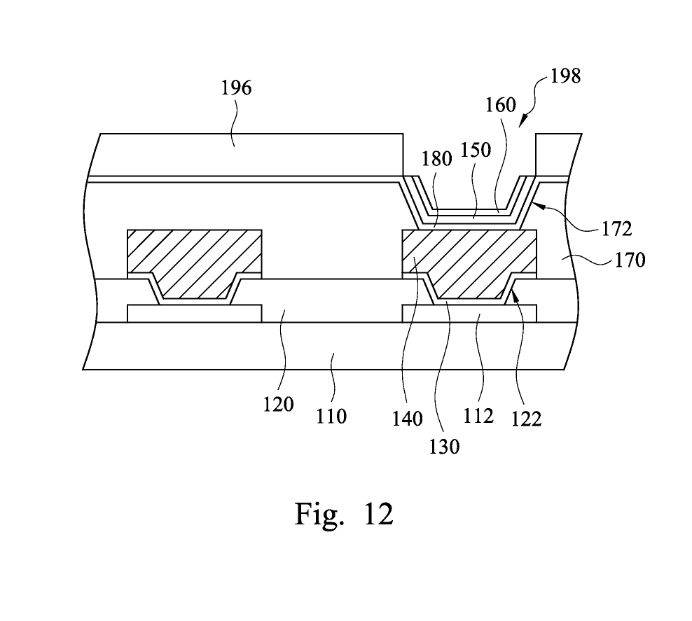

FIG. 12 is a cross-sectional view of the diffusion barrier layer 150 and the oxidation barrier layer 160 after being sequentially formed on the second conductive layer 180 that is exposed through the second photo-resistant layer opening 198 shown in FIG. 11. As shown in FIG. 11 and FIG. 12, after the second conductive layer 180 in the passivation layer opening 172 is exposed through the second photo-resistant layer opening 198, the diffusion barrier layer 150 and the oxidation barrier layer 160 may be sequentially electroplated on the second conductive layer 180 that is exposed through the second photo-resistant layer opening 198, such that the diffusion barrier layer 150 and the oxidation barrier layer 160 are located on the copper bump 140 that is exposed through the passivation layer opening 172.

As shown in FIG. 2 and FIG. 12, after the diffusion barrier layer 150 and the oxidation barrier layer 160 are formed on the second conductive layer 180, the second photo-resistant layer 196 and the second conductive layer 180 not covered by the diffusion barrier layer 150 and the oxidation barrier layer 160 may be removed. For example, an etching process may be performed to remove the second conductive layer 180 not covered by the diffusion barrier layer 150 and the oxidation barrier layer 160. As a result, the inductor structure 100 shown in FIG. 2 may be obtained.

Compared with the prior art, the inductor structure and the manufacturing method thereof of the present invention may form the diffusion barrier layer and the oxidation barrier layer on selected copper bumps, such that the diffusion barrier layer and the oxidation barrier layer are formed on the copper bumps that need to be electrically connected to the conductive protruding portions or BGA during the next process (e.g., a bumping process or a BGA process), and the diffusion barrier layer and the oxidation barrier layer are not formed on other copper bumps. As a result, the material costs of the diffusion barrier layer and the oxidation barrier layer may be reduced by the inductor structure and the manufacturing method thereof, and the entire impedance of lines of the inductor structure can be reduced to increase the efficiency of the inductor structure, such that the inductor quality factor of the inductor structure may be improved.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An inductor structure comprising:
a substrate having a plurality of bond pads;
a protection layer located on the substrate and the bond pads and having a plurality of protection layer openings, wherein the bond pads are respectively exposed through the protection layer openings;
a patterned first conductive layer located on surfaces of the bond pads and the protection layer adjacent to the protection layer openings;
a plurality of copper bumps located on the first conductive layer;
a passivation layer located on the protection layer and the copper bumps and having at least one passivation layer opening, wherein at least one of the copper bumps is exposed through the passivation layer opening;
a diffusion barrier layer located on the copper bump exposed through the passivation layer opening; and
an oxidation barrier layer located on the diffusion barrier layer.

2. The inductor structure of claim 1, further comprising:
a strengthening layer between the diffusion barrier layer and the oxidation barrier layer.

3. The inductor structure of claim 2, wherein the strengthening layer is made of a material comprising palladium.

4. The inductor structure of claim 1, wherein the passivation layer is made of a material comprising oxide or nitride.

5. The inductor structure of claim 1, wherein the protection layer is made of a material comprising oxide or nitride.

6. The inductor structure of claim 1, further comprising:
a second conductive layer between the diffusion barrier layer and the copper bump exposed through the passivation layer opening.

7. The inductor structure of claim 1, wherein the diffusion barrier layer is made of a material comprising nickel.

8. The inductor structure of claim 1, wherein the oxidation barrier layer is made of a material comprising gold.

9. A manufacturing method of an inductor structure comprising:
(a) providing a substrate having a plurality of bond pads;
(b) forming a protection layer having a plurality of protection layer openings on the substrate and the bond pads, such that the bond pads are respectively exposed through the protection layer openings;
(c) forming a first conductive layer on the bond pads and the protection layer;
(d) forming a patterned first photo-resistant layer on the first conductive layer, such that the first conductive layer adjacent to the protection layer openings is exposed through a plurality of first photo-resistant layer openings;
(e) respectively forming a plurality of copper bumps on the first conductive layer in the first photo-resistant layer openings;
(f) removing the first photo-resistant layer and the conductive layer not covered by the copper bumps;
(g) forming a patterned passivation layer on the protection layer and the copper bumps, and at least one of the copper bumps exposed through a passivation layer opening; and
(h) sequentially forming a diffusion barrier layer and an oxidation barrier layer on the copper bump exposed through the passivation layer opening.

10. The manufacturing method of the inductor structure of claim 9, wherein step (h) comprises:
(i) forming a second conductive layer on the passivation layer and the copper bump exposed through the passivation layer opening;
(j) forming a patterned second photo-resistant layer on the second conductive layer, and the second conductive layer in the passivation layer opening exposed through a second photo-resistant layer opening;
(k) sequentially forming the diffusion barrier layer and the oxidation barrier layer on the second conductive layer exposed through the second photo-resistant layer opening; and
(l) removing the second photo-resistant layer and the second conductive layer not covered by the diffusion barrier layer and the oxidation barrier layer.

11. The manufacturing method of the inductor structure of claim 10, wherein step (k) comprises:
electroplating the diffusion barrier layer and the oxidation barrier layer on the second conductive layer exposed through the second photo-resistant layer opening.

12. The manufacturing method of the inductor structure of claim 9, wherein step (h) comprises:
chemically plating the diffusion barrier layer and the oxidation barrier layer on the copper bump exposed through the passivation layer opening.

13. The manufacturing method of the inductor structure of claim 9, wherein step (h) further comprises:
forming a strengthening layer between the diffusion barrier layer and the oxidation barrier layer.

14. The manufacturing method of the inductor structure of claim 9, wherein step (b) comprises:
patterning the protection layer, such that the protection layer has the protection layer openings.

15. The manufacturing method of the inductor structure of claim 9, wherein step (e) comprises:
electroplating the copper bumps on the first conductive layer in the first photo-resistant layer openings.

16. The manufacturing method of the inductor structure of claim 9, wherein step (f) comprises:
etching the first conductive layer not covered by the copper bumps.
